(19) United States
(12) Patent Application Publication
(10) Pub. No.: US 2015/0296607 A1
(43) Pub. Date: Oct. 15, 2015

(54) Electronic Device With Flexible Printed Circuit Strain Gauge Sensor

(71) Applicant: APPLE INC., Cupertino, CA (US)

(72) Inventors: Henry H. Yang, Los Gatos, CA (US); Matthew E. Last, Santa Clara, CA (US); Tongbi T. Jiang, Santa Clara, CA (US)

(73) Assignee: APPLE INC., Cupertino, CA (US)

(21) Appl. No.: 14/251,227

(22) Filed: Apr. 11, 2014

(51) Int. Cl. H05K 1/02; H05K 1/09; H05K 1/03; G01B 7/16; H05K 1/18

(52) U.S. Cl. CPC H05K 1/028; G01B 7/20; H05K 1/181; H05K 1/03; H05K 1/09; H05K 2201/0154

(57) ABSTRACT

An electronic device may be provided with a flexible printed circuit. The flexible printed circuit may have layers of metal and dielectric. Strain gauge resistors may be formed from a strain gauge metal such as constantan. The strain gauge metal may be formed within the flexible printed circuit layers. A strain gauge may include strain gauge circuitry coupled to a strain gauge bridge circuit. Strain gauge resistors for the bridge circuit may be formed from traces that follow parallel meandering paths in the flexible printed circuit layers. A component such as a fingerprint sensor may overlap the strain gauge resistors. Strain gauge resistors may be formed in different overlapping metal layers in the flexible printed circuit layers or may be formed from the same metal layer. Electroplating techniques may be used to form metal traces to which solder balls or wire bonds are coupled.

### BACKGROUND

This relates generally to electronic devices and, more particularly, to electronic devices with components such as strain gauges.

Electronic devices often include sensors. Sensors allow information to be gathered on the operating environment of an electronic device. Sensors can also be used to gather user input.

In some situations, buttons may be used to gather user input. Buttons may be based on mechanical components such as dome switches.

Mechanical button components may be subject to wear during use and may be bulkier than desired. Mechanical button components may also be challenging to integrate with other components.

It would therefore be desirable to be able to provide improved sensors for electronic devices such as strain gauge sensors that can be used in implementing buttons.

### SUMMARY

An electronic device may be provided with a strain gauge formed in a flexible printed circuit. The flexible printed circuit may have layers of metal and dielectric. Strain gauge resistors may be formed from strain gauge metal such as constantan. The strain gauge metal may be formed within the flexible printed circuit layers. A layer of strain gauge metal foil may be laminated to a flexible printed circuit substrate or a layer of strain gauge metal may be deposited onto a flexible printed circuit substrate.

A strain gauge may include strain gauge circuitry coupled to a strain gauge bridge circuit. Strain gauge resistors for the bridge circuit may be formed from traces that follow parallel meandering paths in the flexible printed circuit layers.

A component such as a fingerprint sensor may overlap the strain gauge resistors. Strain gauge resistors may be formed in different overlapping metal layers in the flexible printed circuit layers or may be formed from the same metal layer. Electroplating techniques may be used to form metal traces on the flexible printed circuit to which solder balls or wire bonds are coupled.

An electroplating seed layer may be formed on the flexible printed circuit substrate. The strain gauge resistors may be formed on a first portion of the seed layer and the metal traces may be electroplated on a second portion of the seed layer. If desired, the seed layer may be formed from a layer of strain gauge metal and the metal traces may be electroplated on an exposed portion of the strain gauge metal.

### BRIEF DESCRIPTION OF THE DRAWINGS

FIG. 1 is a perspective view of an illustrative electronic device such as a laptop computer in accordance with an embodiment.

FIG. 2 is a perspective view of an illustrative electronic device such as a handheld electronic device in accordance with an embodiment.

FIG. 3 is a perspective view of an illustrative electronic device such as a tablet computer in accordance with an embodiment.

FIG. 4 is a perspective view of an illustrative electronic device such as a computer or other equipment with a display in accordance with an embodiment.

FIG. 5 is a schematic diagram of illustrative circuitry in an electronic device in accordance with an embodiment.

FIG. 6 is a cross-sectional side view of an illustrative electronic device in accordance with an embodiment.

FIG. 7 is a cross-sectional side view of a flexible printed circuit in accordance with an embodiment.

FIG. 8 is a cross-sectional side view of a portion of a flexible printed circuit to which an electrical component has been mounted in accordance with an embodiment.

FIG. 9 is a cross-sectional side view of a flexible printed circuit having a single layer of patterned metal traces in accordance with an embodiment.

FIG. 10 is a cross-sectional side view of a flexible printed circuit having patterned metal traces formed on opposing upper and lower surfaces of a polymer substrate layer in accordance with an embodiment.

FIG. 11 is a cross-sectional side view of an illustrative flexible printed circuit in accordance with an embodiment.

FIG. 12 is a cross-sectional side view of an illustrative conductive via in a flexible printed circuit in accordance with an embodiment.

FIG. 13 is a schematic diagram of illustrative equipment that may be used in processing structures in accordance with an embodiment.

FIG. 14 is a cross-sectional side view of an illustrative electronic device that includes a strain gauge on a flexible printed circuit in accordance with an embodiment.

FIG. 15 is a cross-sectional side view of an illustrative electronic device having an electronic component such as a fingerprint sensor on a flexible printed circuit with a strain gauge in accordance with an embodiment.

FIG. 16 is a top view of an illustrative strain gauge resistor formed from a meandering metal trace in accordance with an embodiment.

FIG. 17 is a circuit diagram of illustrative strain gauge circuitry that forms a strain gauge in accordance with an embodiment.

FIG. 18 is a top view of an illustrative pair of co-located strain gauge resistors formed from first and second parallel meandering trace paths that run alongside each other in accordance with an embodiment.

FIG. 19 is a top view of an illustrative strain gauge resistor trace coupled to a metal trace forming a signal path in a flexible printed circuit board in accordance with an embodiment.

FIG. 20 is a cross-sectional side view of a flexible printed circuit substrate in accordance with an embodiment.

FIG. 21 is a cross-sectional side view of the flexible printed circuit substrate of FIG. 20 following deposition of a seed layer in accordance with an embodiment.

FIG. 22 is a cross-sectional side view of the flexible printed circuit substrate of FIG. 21 following deposition and patterning of a photoresist layer on the seed layer in accordance with an embodiment.

FIG. 23 is a cross-sectional side view of the flexible printed circuit substrate of FIG. 22 following deposition of a layer of strain gauge metal in accordance with an embodiment.

FIG. 24 is a cross-sectional side view of the flexible printed circuit substrate of FIG. 23 following removal of the photoresist to pattern the strain gauge metal into meandering resistor paths in accordance with an embodiment.

FIG. 25 is a cross-sectional side view of the flexible printed circuit substrate of FIG. 24 following deposition and patterning of a photoresist layer in accordance with an embodiment.

FIG. 26 is a cross-sectional side view of the flexible printed circuit substrate of FIG. 25 following electroplating of a metal trace in the exposed portion of the seed layer of FIG. 25 in accordance with an embodiment.

FIG. 27 is a cross-sectional side view of the flexible printed circuit substrate of FIG. 26 after stripping the photoresist from the substrate in accordance with an embodiment.

FIG. 28 is a cross-sectional side view of the flexible printed circuit substrate of FIG. 27 after adding a patterned cover layer in accordance with an embodiment.

FIG. 29 is a cross-sectional side view of the flexible printed circuit substrate of FIG. 28 following attachment of a die for a fingerprint sensor or other electronic component in accordance with an embodiment.

FIG. 30 is a flow chart of illustrative steps involved in forming a flexible printed circuit with a strain gauge in accordance with an embodiment.

FIG. 31 is a cross-sectional side view of an illustrative flexible printed circuit with a strain gauge in accordance with an embodiment.

FIG. 32 is a cross-sectional side view of a flexible printed circuit substrate in accordance with an embodiment.

FIG. 33 is a cross-sectional side view of the flexible printed circuit substrate of FIG. 32 following lamination of a layer of strain gauge foil to the flexible printed circuit substrate in accordance with an embodiment.

FIG. 34 is a cross-sectional side view of the flexible printed circuit substrate of FIG. 33 following deposition and patterning of a layer of photoresist in accordance with an embodiment.

FIG. 35 is a cross-sectional side view of the flexible printed circuit substrate of FIG. 34 after stripping the photoresist from the flexible printed circuit substrate in accordance with an embodiment.

FIG. 36 is a cross-sectional side view of the flexible printed circuit substrate of FIG. 35 following deposition and patterning of a layer of photoresist in accordance with an embodiment.

FIG. 37 is a cross-sectional side view of the flexible printed circuit substrate of FIG. 36 after performing electroplating operations to grow a metal trace on an exposed portion of the patterned strain gauge foil in accordance with an embodiment.

FIG. 38 is a flow chart of illustrative steps involved in forming a strain gauge from a laminated foil layer of strain gauge metal on a flexible printed circuit substrate in accordance with an embodiment.

FIG. 39 is a cross-sectional side view of an illustrative flexible printed circuit with a two-layer strain gauge having overlapping strain gauge resistors in respective metal layers of the flexible printed circuit layers of a flexible printed circuit in accordance with an embodiment.

### DETAILED DESCRIPTION

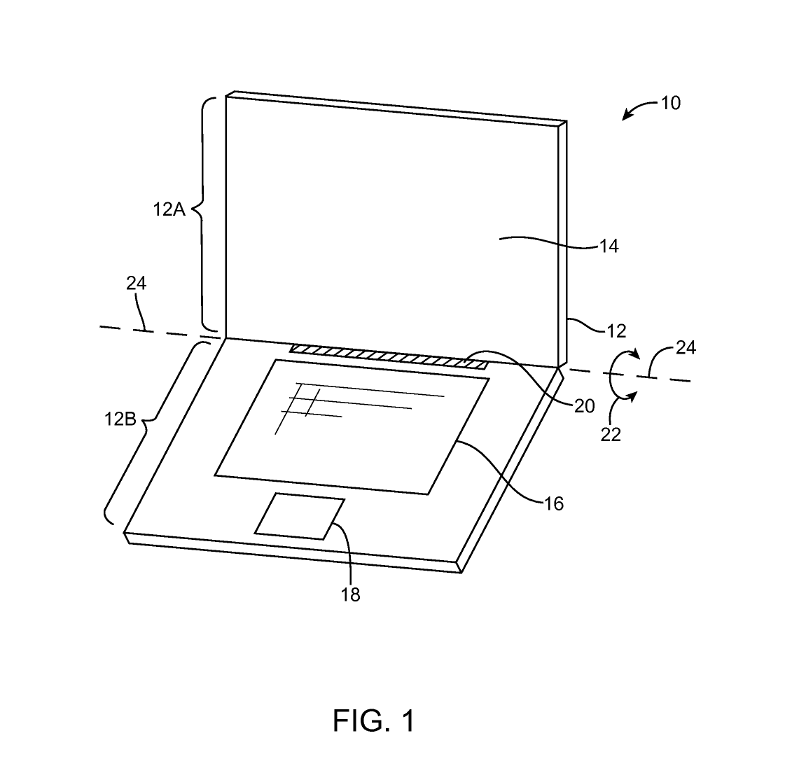

Electronic devices may be provided with printed circuits. The printed circuits may include rigid printed circuit boards (e.g., printed circuits formed from rigid printed circuit board material such as fiberglass-filled epoxy) and flexible printed circuits (e.g., printed circuits that include one or more sheets of polyimide substrate material or other flexible polymer layers). The flexible printed circuits may be provided with strain gauges. Illustrative electronic devices that may be provided with flexible printed circuits having strain gauges are shown in FIGS. 1, 2, 3, and 4.

Electronic device 10 of FIG. 1 has the shape of a laptop computer and has upper housing 12A and lower housing 12B with components such as keyboard 16 and touchpad 18. Device 10 has hinge structures 20 (sometimes referred to as a clutch barrel) to allow upper housing 12A to rotate in directions 22 about rotational axis 24 relative to lower housing 12B. Display 14 is mounted in housing 12A. Upper housing 12A, which may sometimes referred to as a display housing or lid, is placed in a closed position by rotating upper housing 12A towards lower housing 12B about rotational axis 24.

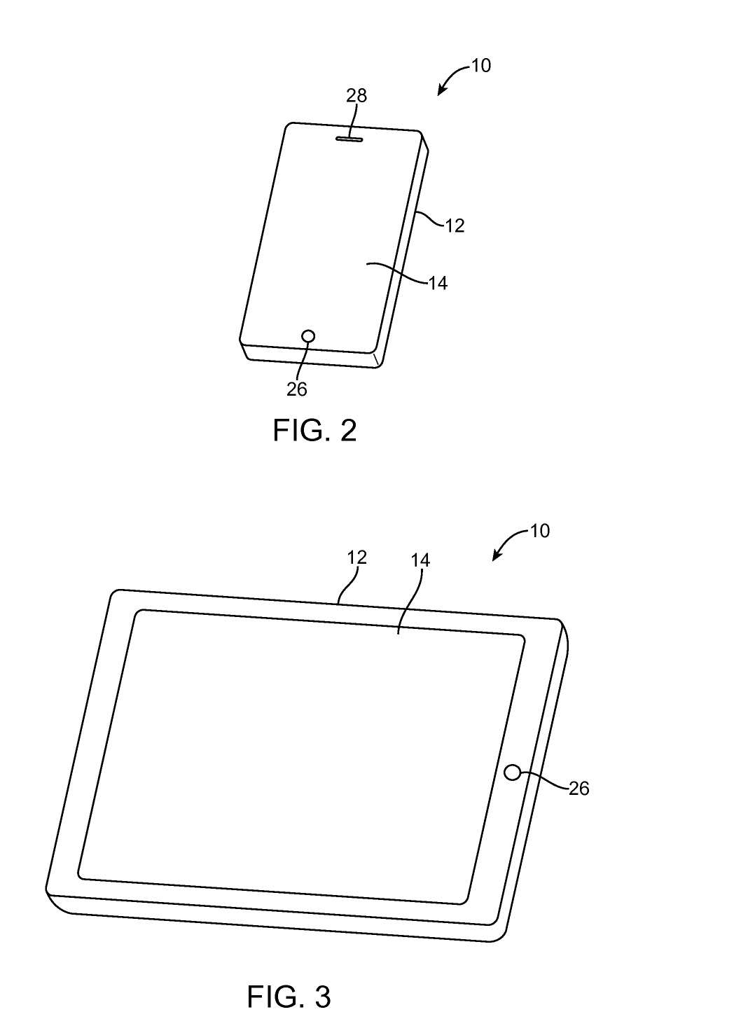

FIG. 2 shows an illustrative configuration for electronic device 10 based on a handheld device such as a cellular telephone, music player, gaming device, navigation unit, or other compact device. In this type of configuration for device 10, device 10 has opposing front and rear surfaces. The rear surface of device 10 may be formed from a planar portion of housing 12. Display 14 forms the front surface of device 10. Display 14 may have an outermost layer that includes openings for components such as button 26 and speaker port 28.

In the example of FIG. 3, electronic device 10 is a tablet computer. In electronic device 10 of FIG. 3, device 10 has opposing planar front and rear surfaces. The rear surface of device 10 is formed from a planar rear wall portion of housing 12. Curved or planar sidewalls may run around the periphery of the planar rear wall and may extend vertically upwards. Display 14 is mounted on the front surface of device 10 in housing 12. As shown in FIG. 3, display 14 has an outermost layer with an opening to accommodate button 26.

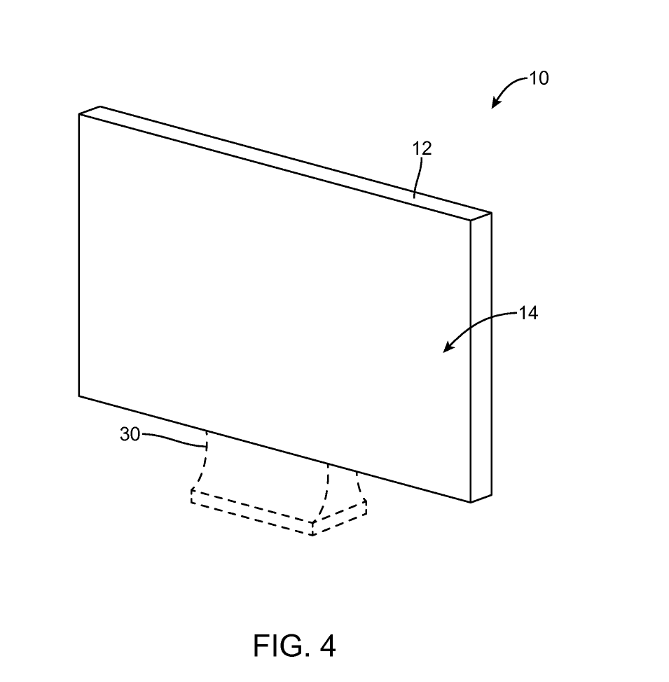

FIG. 4 shows an illustrative configuration for electronic device 10 in which device 10 is a computer display, a computer that has an integrated computer display, or a television. Display 14 is mounted on a front face of device 10 in housing 12. With this type of arrangement, housing 12 for device 10 may be mounted on a wall or may have an optional structure such as support stand 30 to support device 10 on a flat surface such as a table top or desk.

An electronic device such as electronic device 10 of FIGS. 1, 2, 3, and 4, may, in general, be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. The examples of FIGS. 1, 2, 3, and 4 are merely illustrative.

Device 10 may include a display such as display 14. Display 14 may be mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of display pixels formed from liquid crystal display (LCD) components, an array of electrophoretic display pixels, an array of plasma display pixels, an array of organic light-emitting diode display pixels, an array of electrowetting display pixels, or display pixels based on other display technologies.

Display 14 may be protected using a display cover layer such as a layer of transparent glass or clear plastic. Openings may be formed in the display cover layer. For example, an opening may be formed in the display cover layer to accommodate a button, an opening may be formed in the display cover layer to accommodate a speaker port, etc.

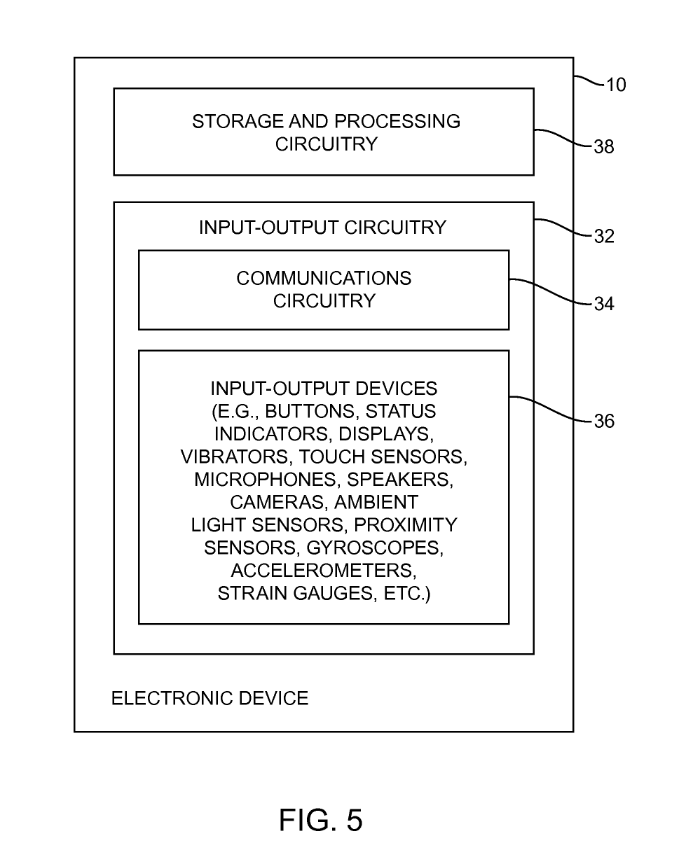

A schematic diagram of an illustrative device such as devices 10 of FIGS. 1, 2, 3, and 4 is shown in FIG. 5. As shown in FIG. 5, electronic device 10 may include control circuitry such as storage and processing circuitry 38. Storage and processing circuitry 38 may include one or more different types of storage such as hard disk drive storage, nonvolatile memory (e.g., flash memory or other electrically-programmable-read-only memory), volatile memory (e.g., static or dynamic random-access-memory), etc. Processing circuitry in storage and processing circuitry 38 may be used in controlling the operation of device 10. The processing circuitry may be based on a processor such as a microprocessor and other suitable integrated circuits. With one suitable arrangement, storage and processing circuitry 38 may be used to run software on device 10, such as internet browsing applications, email applications, media playback applications, operating system functions, software for capturing and processing images, software implementing functions associated with gathering and processing sensor data such as stress data, etc.

Input-output circuitry 32 may be used to allow data to be supplied to device 10 and to allow data to be provided from device 10 to external devices. Input-output circuitry 32 may include wired and wireless communications circuitry 34. Communications circuitry 34 may include radio-frequency (RF) transceiver circuitry formed from one or more integrated circuits, power amplifier circuitry, low-noise input amplifiers, passive RF components, one or more antennas, and other circuitry for handling RF wireless signals. Wireless signals can also be sent using light (e.g., using infrared communications).

Input-output circuitry 32 may include input-output devices 36. Input-output devices 36 may include devices such as buttons (see, e.g., button 26 of FIGS. 2 and 3), joysticks, click wheels, scrolling wheels, a touch screen (see, e.g., display 14), other touch sensors such as track pads (see, e.g., track pad 18 of FIG. 1), touch-sensor-based buttons, vibrators, audio components such as microphones and speakers, image capture devices such as a camera module having an image sensor and a corresponding lens system, keyboards, status-indicator lights, tone generators, key pads, strain gauges (e.g., a button based on a strain gauge), proximity sensors, ambient light sensors, capacitive proximity sensors, light-based proximity sensors, gyroscopes, accelerometers, magnetic sensors, temperature sensors, fingerprint sensors, and other equipment for gathering input from a user or other external source and/or generating output for a user.

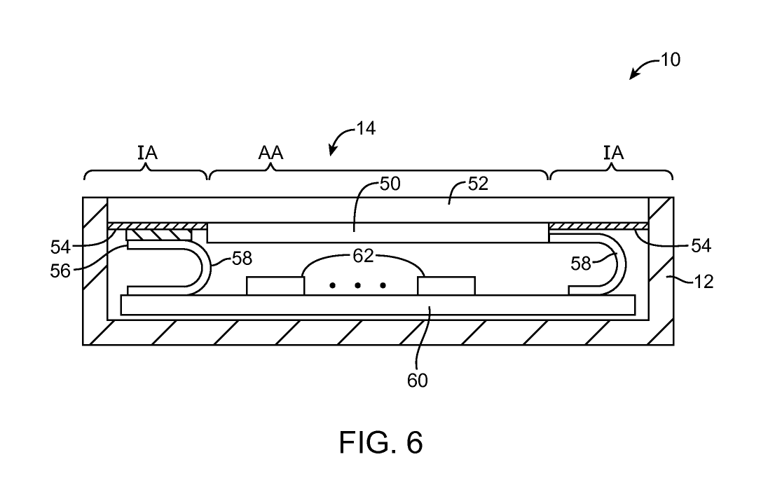

A cross-sectional side view of an illustrative electronic device of the type that may be provided with one or more flexible printed circuits is shown in FIG. 6. As shown in the illustrative configuration of FIG. 6, device 10 may have a display such as display 14 that is mounted on the front face of device 10. Display 14 may have a display cover layer such as cover layer 52 and a display module such as display module 50. Display cover layer 52 may be formed from a glass or plastic layer. Display module 50 may be, for example, a liquid crystal display module or an organic light-emitting diode display layer (as examples). Display module 50 may have a rectangular outline when viewed from the front of device 10 and may be mounted in a central rectangular active area AA on the front of device 10. An inactive area IA that forms a border for display 14 may surround active area AA. Opaque masking material such as black ink 54 may be used to coat the underside of cover layer 52 in inactive area IA.

Device 10 may include components such as components 62 that are mounted on one or more printed circuit boards such as printed circuit board 60. Printed circuit board 60 may have one or more layers of dielectric material and one or more layers of metal traces. Printed circuit board 60 of FIG. 6 may be a rigid printed circuit board or a flexible printed circuit board. Components 62 may be, for example, integrated circuits, discrete components such as capacitors, resistors, and inductors, switches, connectors, sensors, input-output devices such as status indicators lights, audio components, or other electrical and/or mechanical components for device 10. Components 62 may be attached to printed circuit 54 using solder, welds, anisotropic conductive film or other conductive adhesives, or other conductive connections. One or more layers of patterned metal interconnects (i.e., copper traces or metal traces formed from other materials) may be formed within one or more dielectric layers in printed circuit board 60 to form signal lines that route signals between components 62.

If desired, device 10 may have components mounted on the underside of display cover layer 52 such as illustrative component 56 on opaque masking layer 54 in inactive area IA of device 10 of FIG. 6. Component 56 may be a touch sensor, a fingerprint sensor, a strain gauge sensor, a button, or other input-output device 36 (as examples).

Flexible printed circuits 58 may have layers of dielectric and layers of metal traces. The metal traces of flexible printed circuits 58 may be used to form signal paths to interconnect the circuitry of device 10. For example, flexible printed circuits 58 may have signal paths that interconnect component 56 to the circuitry of components 62 on printed circuit 60, signal path that couple display module 50 to components 62 on printed circuit 60, or signal paths for interconnecting other components in device 10. Strain gauge structures such as strain gauge resistors may also be formed in flexible printed circuits 58.

Flexible printed circuits such as illustrative flexible printed circuits 58 of FIG. 6 are often bent. The ability to bend flexible printed circuits in device 10 helps a device designer to route signals in tight spaces and in portions of a device where a planar printed circuit would be ineffective or cumbersome.

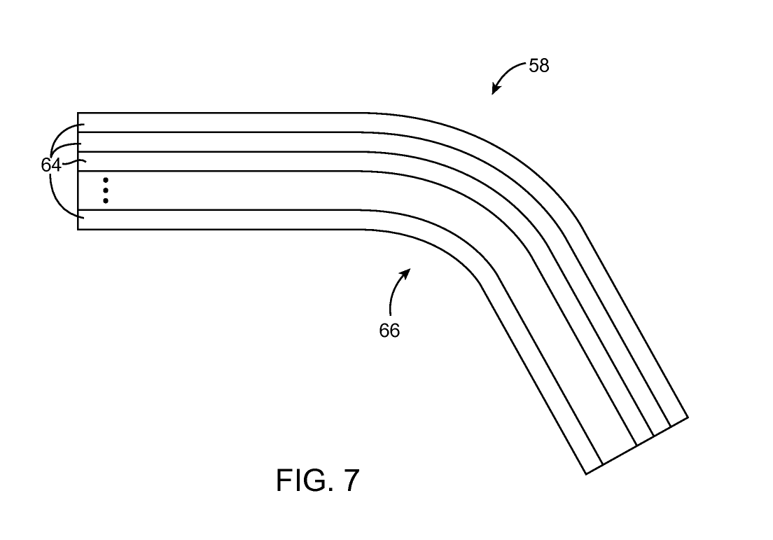

A cross-sectional side view of an illustrative flexible printed circuit is shown in FIG. 7. As shown in FIG. 7, flexible printed circuit 58 may have a bend such as bend 66. Flexible printed circuit 58 may include multiple layers of material such as layers 64. Layers 64 may include one or more metal layers, one or more dielectric layers, and one or more adhesive layers (or no adhesive layers). Metal traces formed from the metal layers may be used to carry electrical signals. Examples of metals that may be used in the metal layers of layers 64 in flexible printed circuit 58 include copper, nickel, gold, and aluminum. Examples of dielectric materials that may be used in forming the dielectric layers of layers 64 in flexible printed circuit 58 include polyimide, acrylic, and other polymers. Examples of adhesives that may be used in forming the adhesive layers of layers 64 in flexible printed circuit 58 include acrylic adhesives and epoxy adhesives. Other types of metal, dielectric, and adhesive may be used in forming layers 60 if desired. These are merely illustrative examples. Moreover, strain gauge resistor metal may be incorporated into flexible printed circuit 58. For example, a metal alloy such as constantan (an alloy of copper and nickel) may be used in flexible printed circuit 58 to form strain gauge resistors for a strain gauge.

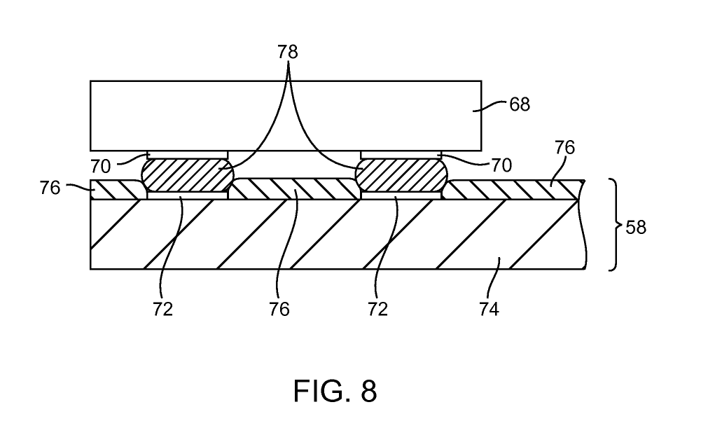

Electrical components such as illustrative electrical component 68 of FIG. 8 may be attached to flexible printed circuit 58. Components that may be attached to flexible printed circuit 58 in this way include connectors (e.g., all or part of a board-to-board connector, a zero insertion force connector, or other connector), integrated circuits, discrete components such as resistors, capacitors, and inductors, switching circuitry, and other circuitry (see, e.g., circuitry 38 and 32 of FIG. 5). Electrical and physical connections between component 68 and flexible printed circuit 58 may be made using solder, conductive adhesive, welds, or other conductive coupling mechanisms. In the illustrative configuration of FIG. 8, component 68 has metal contacts (solder pads) 70 and flexible printed circuit 58 has corresponding metal contacts (solder pads 72). A patterned dielectric layer such as a layer of polyimide or other polymer (sometimes referred to as a solder mask or cover layer) such as layer 76 may serve as the outermost layer of flexible printed circuit 58 (e.g., layer 76 may be formed on top of other layers in flexible printed circuit 58 such as the metal layer used in forming solder pads 72 and other layers 74 of metal, dielectric, and adhesive). If desired, a dielectric cover layer (e.g., a polyimide cover layer) may be formed on both the upper and lower surfaces of the layers of flexible printed circuit 58 (e.g., in a configuration in which metal traces are formed on upper and lower surfaces of an internal polyimide substrate layer). As shown in FIG. 8, openings in layer 76 may be formed to accommodate solder pads 72 and to help control the lateral spread of solder 70 when using solder 70 to solder component 68 to flexible printed circuit 58.

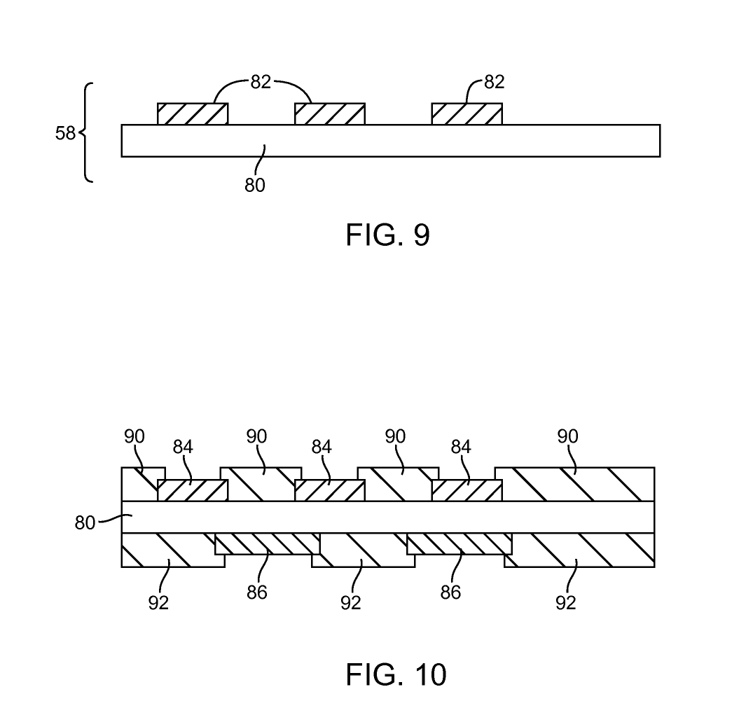

FIG. 9 shows how flexible printed circuit 58 may have signal paths formed from a patterned metal layer on a dielectric substrate. In the example of FIG. 9, flexible printed circuit 58 has a flexible dielectric substrate such as substrate 80 (e.g., a flexible polyimide layer) that has been covered with a patterned layer of metal traces 82 formed directly on the surface of substrate 80. If desired, additional layers of material (e.g., an adhesive layer, a polymer cover layer, etc.) may be formed on top of the flexible printed circuit 58 of FIG. 9 and/or below substrate 80. The FIG. 9 arrangement is a single-metal-layer flexible printed circuit. Flexible printed circuit configurations with two or more layers of metal may also be used.

FIG. 10 is a cross-sectional side view of flexible printed circuit 58 in a configuration in which flexible printed circuit 58 has been provided with two layers of patterned metal. As shown in FIG. 10, flexible printed circuit 58 has a polymer substrate such as a polyimide substrate (substrate 80). Substrate 80 has opposing upper and lower surfaces. Metal traces 84 of FIG. 10 are formed directly on the upper surface of substrate 80. Metal traces 86 are formed directly on the lower surface of substrate 80. A polymer cover layer such a layer 90 may be used to cover the upper metal layer used in forming metal traces 84. A polymer cover layer or other dielectric material 92 may be used to cover the lower metal layer used in forming metal traces 86. Openings may be formed in insulating layers such as polymer layers 90 and 92 (e.g., to allow components to be soldered to traces 84 and/or 86). A patterned dielectric layer such as a polymer layer with openings may also be formed over traces 82 of flexible printed circuit 58 of FIG. 9.

The outermost dielectric layers of flexible printed circuit 58 (i.e., the cover layers for flexible printed circuit 58) may be formed from a laminated polymer film (e.g., a polyimide film attached to flexible printed circuit 58 with a layer of adhesive), may be formed from a cured liquid polymer (e.g., photoimageable polymer formed directly on underlying layers without adhesive), or may be formed from other dielectric materials formed directly on underlying metal traces or other structures on the surface of printed circuit 58 and/or attached to underlying metal traces or other structures on the surface of printed circuit 58 using adhesive. Metal traces 82 may be formed directly on the surface of substrate 80 as shown in the examples of FIGS. 9 and 10 or may be laminated to substrate 80 using adhesive. For example, traces 82 in FIG. 9 may be formed by laminating a metal foil layer to substrate 80 with an interposed layer of adhesive). If desired, three or more metal layers may be formed in flexible printed circuit 58, as described in connection with FIG. 7. In configurations for printed circuit 58 that contain multiple metal layers, multiple intervening substrate layers may, if desired, be used to separate metal layers. For example, there may be two or more polyimide substrate layers in printed circuit 58. Adhesive layers, metal layers, substrate layers, and polymer cover layers (sometimes referred to as solder mask layers or coverlay) may be arranged in a stack in a desired pattern to form flexible printed circuit 58. The use of a single-layer design for flexible printed circuit 58 of FIG. 9 and a two-layer design for flexible printed circuit 58 of FIG. 10 is merely illustrative.

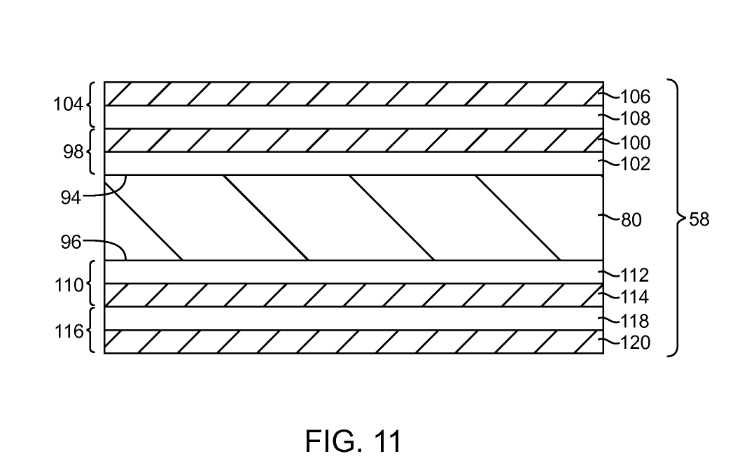

FIG. 11 is a cross-sectional side view of an illustrative two-layer flexible printed circuit showing how both the upper and lower surfaces of substrate 80 may be covered with layers of material that are attached to substrate 80 using adhesive. As shown in FIG. 11, flexible printed circuit 58 is formed using a substrate layer such as substrate 80 (e.g., a polyimide layer or other suitable layer). Substrate 80 has upper surface 94 and opposing lower surface 96. Layer 98 may be formed on upper surface 94. Layer 98 may include metal layer 100 and adhesive layer 102. Adhesive layer 102 may be used to laminate metal layer 100 to upper surface 94 of substrate 80. Layer 104 may be formed on top of layer 98. Layer 104 may include polymer layer 106 such as a polyimide layer (sometimes referred to as a cover layer, coverlay, or solder mask). Adhesive layer 108 in layer 104 may be used to attach polymer layer 106 to layer 98. The underside of flexible printed circuit substrate 80 may be provided with layers 110 and 116. Layer 110 may include metal layer 114. Adhesive layer 112 in layer 110 may be used to attach metal layer 114 to lower surface 96 of substrate 80. Layer 116 may include dielectric layer 120 (e.g., a polymer cover layer such as a polyimide layer) and adhesive layer 118 for attaching layer 120 to layer 110. Metal layers in flexible printed circuit 58 such as metal layer 114 and metal layer 100 of FIG. 11 may be patterned using photolithography, laser cutting, die cutting (e.g., foil stamping techniques), or other patterning techniques. Dielectric layers 106 and 120 and/or the adhesive layers in flexible printed circuit 58 may also be patterned using these techniques.

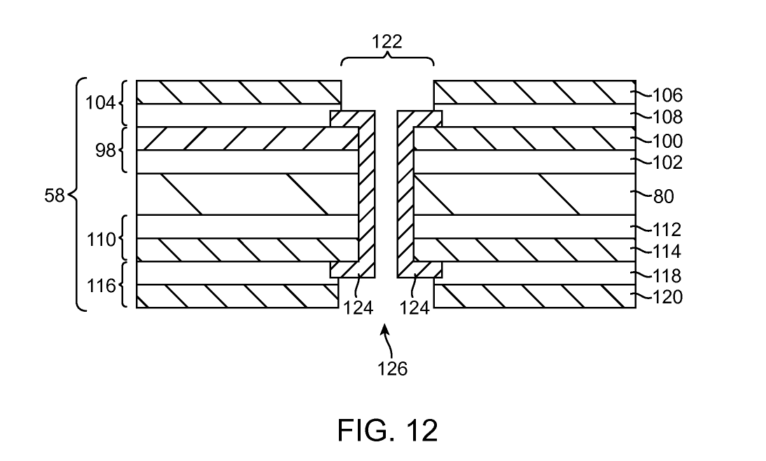

If desired, through vias, blind vias, and buried vias may be used to interconnect metal traces on different layers of flexible printed circuit 58. Holes or other openings may be formed in flexible printed circuit 58 using laser drilling, stamping, machining, or other hole formation techniques. The holes may be filled with metal using electroplating, electroless deposition, or other metal deposition techniques. Plated holes may form tubular vias that form conductive signal paths between the metal layers of flexible printed circuit 58. As shown in FIG. 12, for example, the layers of flexible printed circuit 58 may be provided with holes such as hole 122. Metal 124 may be deposited on the inner surface of hole 122 using electrochemical deposition (e.g., electroplating and/or electroless deposition), thereby forming via 126. Via 126 can form a signal path between metal layer 100 and metal layer 114. Vias with other configurations (e.g., blind vias and buried vias) can likewise interconnect different metal layers in flexible printed circuit 58.

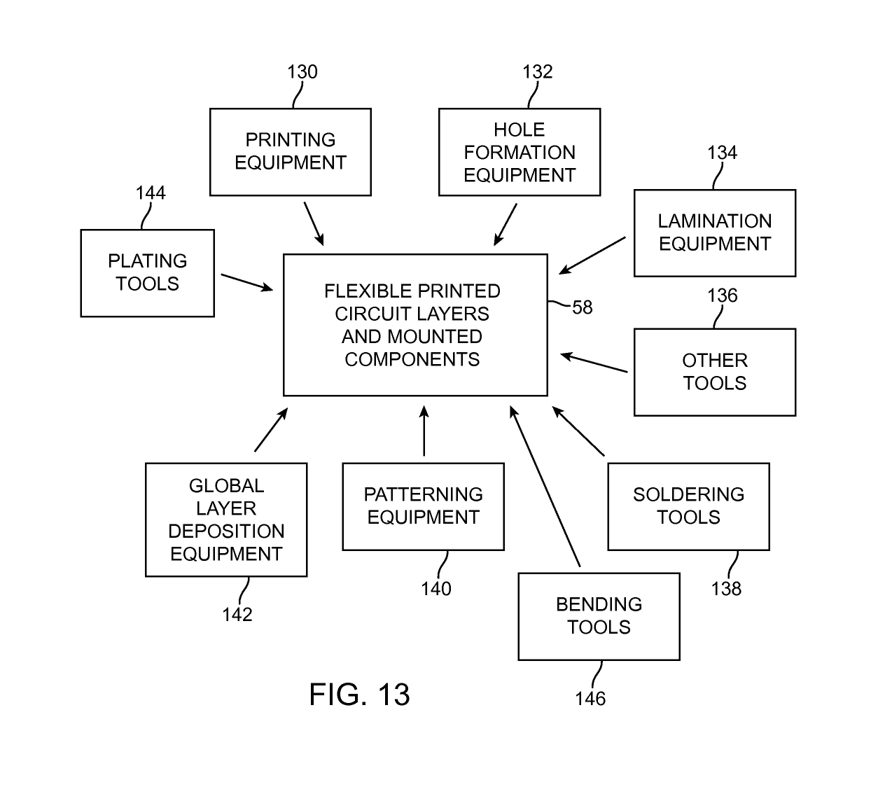

FIG. 13 is a diagram of illustrative processing equipment that may be used in forming flexible printed circuit 58 and in mounting electrical components to flexible printed circuit 58 or otherwise coupling flexible printed circuit 58 into the circuitry of device 10.

The equipment of FIG. 13 may include printing equipment 130. Printing equipment 130 may include ink jet printing equipment, pad printing equipment, screen printing equipment, and other equipment for printing blanket layers and/or patterned layers of material. Examples of structures that may be formed using equipment 130 include printed layers of dielectric, strips of dielectric, metal lines (e.g., metal traces formed from metallic paint or other liquid conductive material), blanket layers of metal, etc.

Hole formation equipment 132 may include tools such as laser drilling tools, machining tools, and other equipment for forming openings in one or more layers of material for flexible printed circuit 58. For example, hole formation equipment 132 may use a laser or other tool to drill holes for vias such as via 126 of FIG. 12.

Lamination equipment 134 may include rollers and other equipment for laminating layers of material together (e.g., using heat and pressure to cause adhesive to attach layers of flexible printed circuit 58 together or to otherwise attach layers together).

Global layer deposition equipment 142 may include equipment for depositing layers of material by blanket spray coating, by spinning, by physical vapor deposition (e.g., sputtering), or other deposition techniques.

Patterning equipment 140 may be used to pattern layers of material such as blanket layers of metal and/or dielectric. Equipment 140 may include photolithographic equipment such as equipment for depositing photoresist or other photoimageable materials, equipment for exposing photoresist or other photoimageable materials to patterned light associated with a photomask, developing equipment to use in developing photoresist or other photoimageable materials, etching equipment for etching the structures of flexible printed circuit 58 after deposited photoresist has been patterned by exposure and development, etc.

Electrochemical deposition tools 144 such as tools for electroplating metal in a via, tools for electroless deposition, and other electrochemical deposition equipment may be used in forming flexible printed circuit 58.

One or more of the layers of flexible printed circuit 58 and/or other structures may be bent using bending tools 146. Bending tools 146 may be formed from stand-alone equipment or equipment that is integrated into other equipment of FIG. 13. Examples of bending equipment that may be used in forming bends in flexible printed circuit 58 include mandrels, presses, grippers, and other bending machines.

If desired, other tools 136 may be used in processing the structures of flexible printed circuit 58 such as lasers for cutting, machining tools for trimming or cutting, heated presses, die cutting equipment, injection molding equipment, heating equipment such as infrared lamps and ovens, light-emitting diodes, or other light sources for adhesive curing (e.g., ultraviolet light-emitting diodes), and other equipment for depositing, patterning, processing, and removing layers of dielectric and metal for structures 58.

Soldering tools 138 and other equipment may be used in mounting electrical components to flexible printed circuit 58 and/or may be used in coupling flexible printed circuit 58 to other circuitry in device 10.

Strain gauge structures may be incorporated into a device such as device 10. A strain gauge may be used, for example, to implement a button. A strain gauge may be based on a network of resistors. The resistors may be formed from a material such as constantan that exhibits changes in resistance when exposed to strain. A Wheatstone bridge circuit or other strain gauge circuit may be used in measuring small resistance changes within stain gauge resistors. Constantan is desirable for use as a strain gauge resistor material because constantan exhibits relatively minimal changes in resistance as a function of temperature. This makes a constantan strain gauge relatively insensitive to environmental temperature fluctuations. If desired, other strain gauge resistor materials may be used in forming a strain gauge for device 10. The use of constantan in forming strain gauge resistors for a strain gauge in device 10 is merely illustrative.

Strain gauge structures such as strain gauge resistors can be formed as an integral portion of a flexible printed circuit. This type of arrangement conserves space within device 10 and can improve performance and reduce complexity.

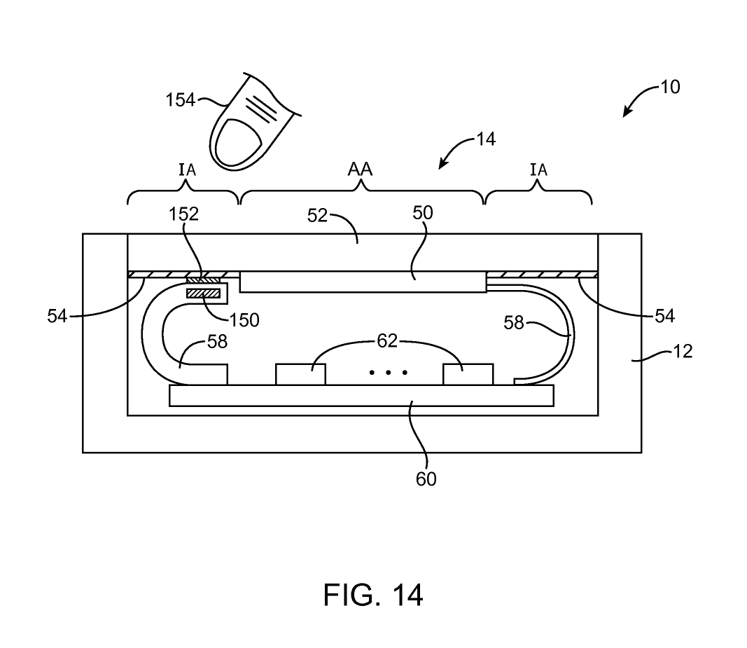

An illustrative configuration for device 10 in which a flexible printed circuit has been provided with a strain gauge (i.e., a strain gauge resistor network) is shown in FIG. 14. As shown in the cross-sectional side view of device 10 in FIG. 14, device 10 may have display 14 mounted in housing 12. Display 14 may include display cover layer 52. Display 14 may have display module 50 in active area AA. Inactive area IA may form a border that runs around the periphery of active area AA. Opaque masking material 54 (e.g., black ink) may be formed on the inner surface of cover layer 52 in inactive area IA.

Device 10 may include components such as components 62 that are mounted on one or more printed circuit boards such as printed circuit board 60. In the illustrative configuration of FIG. 14, the flexible printed circuit 58 that is on the right-hand side of device 10 is used to couple the circuitry of printed circuit board 60 to display module 58. The flexible printed circuit 58 that is on the left-hand side of device 10 includes strain gauge structure 150. Strain gauge structure 150 may include, for example, a network of constantan resistors. The strain gauge resistors may form the sensing portion of a strain gauge and may be mounted at a location in device 10 that is subject to strain. For example, the strain gauge resistors of structure 150 (i.e., the portion of flexible printed circuit 58 that contains the strain gauge resistor network) may be mounted to the underside of display cover layer 52 using adhesive 152. In the presence of pressure from an external object such as a user's finger (finger 154), the strain gauge resistors of structure 150 may exhibit a change in resistance. By detecting finger pressure on display cover layer 52 in this way, the strain gauge structure may be used to implement a thin strain gauge button for device 10. The absence of strain indicates that the user's finger is not pressing down on the strain gauge button. The presence of strain indicates that the user's finger is pressing down on the strain gauge button. If desired, the strain gauge button may also be used to measure intermediate amounts of strain (e.g., to implement a volume control function or other analog control device).

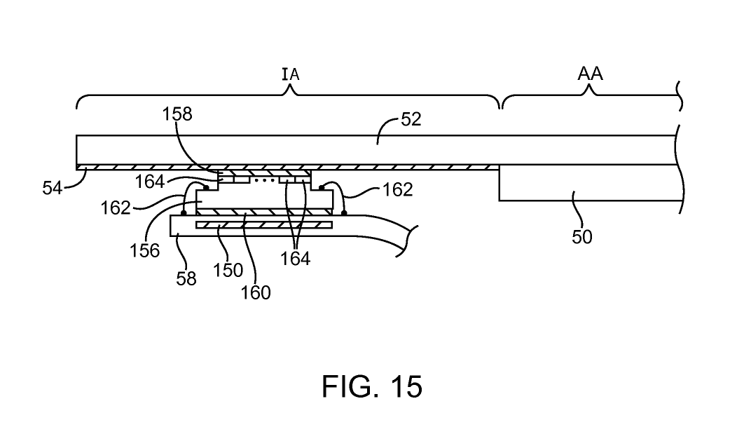

If desired, a fingerprint sensor may be provided in device 10. For example, a fingerprint sensor may overlap strain gauge structure 150. The fingerprint sensor may have electrodes or other structures that are formed in flexible printed circuit 58. As shown in FIG. 15, the fingerprint sensor may, if desired, be implemented using a fingerprint sensor device (e.g., a silicon die) such as fingerprint sensor 156 that is mounted to the upper surface of flexible printed circuit 58. Fingerprint sensor 156 may have an array of fingerprint sensor electrodes such as electrodes 164. A layer of adhesive such as adhesive 158 may be used to attach the array of electrodes 164 and the other circuitry of fingerprint sensor 156 to the inner surface of display cover layer 52. Adhesive 160 may be used to attach fingerprint sensor 156 to flexible printed circuit 58. If desired, other attachment mechanisms such as solder joints, welds, and fasteners, may be used in mounting flexible printed circuit 58 and fingerprint sensor 156 within device 10. The use of adhesive layers such as adhesive layer 158 and adhesive layer 160 is merely illustrative.

Signals may be routed between fingerprint sensor 156 and metal traces on flexible printed circuit 58 using solder joints, conductive adhesive connections, or wire-bond connections formed by wire bonds such as wires bonds 162 of FIG. 15. Strain gauge structure 150 may be formed from a patterned constantan layer or other strain gauge resistors.

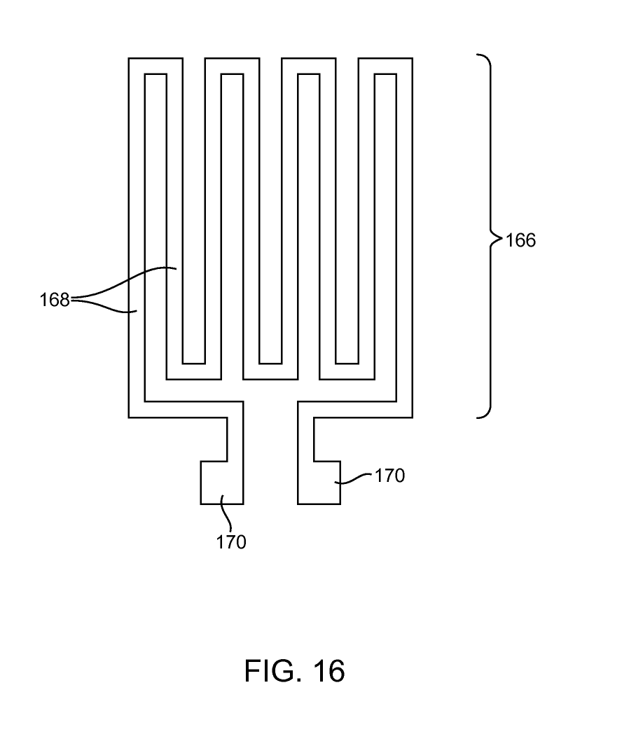

An illustrative strain gauge resistor configuration that may be used for strain gauge structure 150 of FIG. 14 or FIG. 15 is shown in FIG. 16. As shown in FIG. 16, strain gauge resistor 166 may include metal traces patterned to form multiple parallel elongated metal strips in a single meandering path 168 coupled between a pair of resistor terminals 170. When display cover layer 52 and therefore flexible printed circuit 150 on the underside of display cover layer 52 is subjected to stress (e.g., by bending inwardly in response to the application of force by user finger 154 or other external object on the surface of display cover layer 52), the resistance across terminals 170 will change. This change in resistance may be measured using strain gauge resistor monitoring circuitry such as a bridge circuit or other strain gauge circuitry.

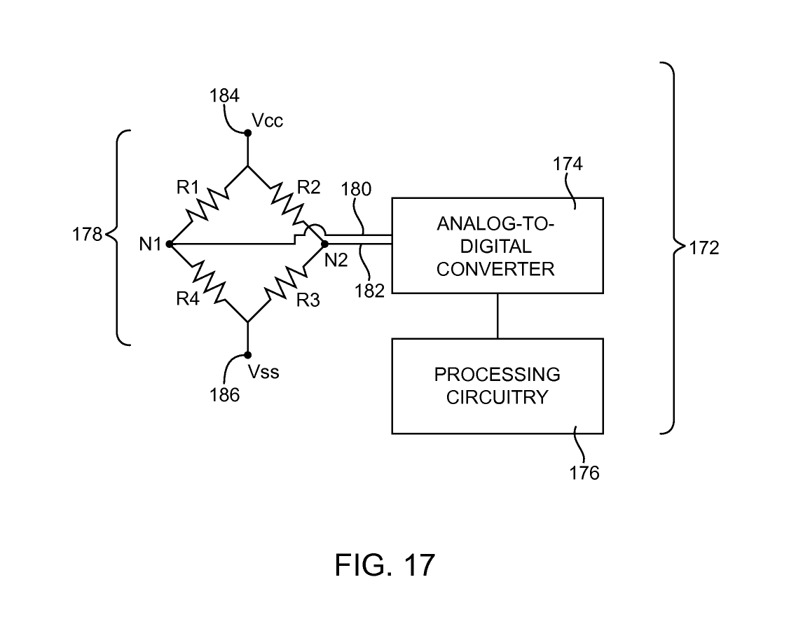

Illustrative strain gauge circuitry (stress data collection circuitry) 172 that may be used in making strain gauge measurements for a strain gauge (e.g., a strain gauge in a strain-gauge button or other component in device 10) is shown in FIG. 17. As shown in FIG. 17, strain gauge circuitry 172 may include strain gauge resistors R1, R2, R3, and R4. One or more of strain gauge resistors R1, R2, R3, and R4 may be implemented using a meandering trace pattern of the type used by strain gauge resistor 166 of FIG. 16.

Strain gauge 172 may include an analog-to-digital converter such as analog-to-digital converter 174 and processing circuitry 176. Analog-to-digital converter circuitry 174 may be coupled to a bridge circuit such as bridge circuit 178 that is formed from resistors R1, R2, R3, and R4 using signal paths 180 and 182. A power supply may provide a power supply voltage Vcc to bridge circuit terminal 184 of bridge circuit 178 and may provide a power supply voltage Vss to bridge circuit terminal 186 of bridge circuit 178. Power supply voltages Vcc and Vss may be, for example, a positive power supply voltage and a ground power supply voltage, respectively.

During operation of strain gauge circuitry 172, a voltage drop of Vcc-Vss will be applied across bridge circuit 178. Resistors R1, R2, R3, and R4 may all nominally have the same resistance value (as an example). In this configuration, bridge circuit 178 will serve as a voltage divider that nominally provides each of paths 180 and 182 with a voltage of (Vcc-Vss)/2. The voltage difference across nodes N1 and N2 will therefore initially be zero.

With one suitable arrangement, resistors R1 and R3 are mounted in flexible printed circuit 58 so that both resistors R1 and R3 will experience similar stresses during use. Resistors R2 and R4 may be located away from resistors R1 and R3 and/or may be oriented so as to avoid being stressed while resistors R1 and R3 are being stressed. This allows resistors R2 and R4 to serve as reference resistors. With this approach, pressure to the strain gauge resistors R1 and R3 in flexible printed circuit 56 from user finger 164 will cause the resistance of resistors R1 and R3 to rise simultaneously while resistors R2 and R4 serve as nominally fixed reference resistors (compensating for drift, temperature changes, etc.). Because both R1 and R3 respond to the application of pressure, analog-to-digital converter 174 will receive a larger signal than a configuration in which only one of the strain gauge resistors in bridge circuit 178 response to the application of pressure. This is because the voltage on path 180 will drop due to the increase in the resistance of resistor R1 while the voltage on path 182 simultaneously rises due to the increase in the resistance of resistor R3. Other types of bridge circuit layout may be used if desired.

Due to the changes in resistance to resistors R1 and R3, the voltage between paths 180 and 182 will vary in proportion to the strain that is being applied to the strain gauge structure 150. Analog-to-digital converter 174 digitizes the voltage signal across paths 180 and 182 and provides corresponding digital strain (stress) data to processing circuitry 176. Processing circuitry 176 and other control circuitry in device 10 can take appropriate action in response to the measured strain data. For example, processing circuitry 176 can convert raw strain data into button press data or other button input information. Device 10 can then respond accordingly (e.g., by using the strain gauge button data as button press data for a menu or home button, etc.).

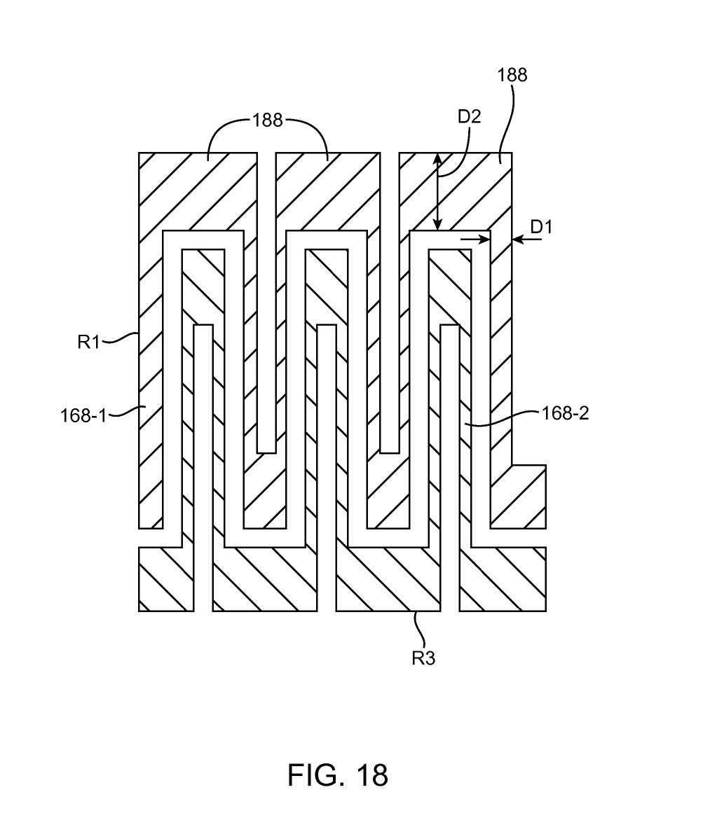

To minimize temperature differentials and other non-uniformities that may affect accuracy in bridge circuit 178, it may be desirable to use a co-located resistor design of the type shown in FIG. 18. As shown in FIG. 18, resistor R1 may be formed from meandering resistor trace 168-1 and resistor R3 may be formed from co-located (adjacent) meandering resistor trace 168-2 that runs alongside trace 168-1 in parallel with trace 168-1. Because traces 168-1 and 168-2 run parallel to each other, traces 168-1 and 168-2 are exposed to similar temperatures and other environmental conditions. This helps reduce noise due to temperature fluctuations in resistors R1 and R3. If desired, the widths of the long thin portions of traces 168-1 and 168-2 (the strips of metal running vertically in the orientation of FIG. 18) may have a width D1 that is less than the width D2 of the perpendicularly extending portions of traces 168-1 and 168-2 such as horizontal portions 188. For example, D1 may be less than one half of D2. This helps ensure that resistance changes (in this example) will be due to compression and elongation of resistors R1 and R3 along the vertical dimension of FIG. 18. Strain gauge structure 150 can be configured so that such vertically-oriented compression and elongation will arise to change the resistances of resistors R1 and R3 when user finger 154 presses against display cover layer 52 while the resistances of R2 and R4 remain constant so that resistances R2 and R4 can serve as reference resistors in bridge circuit 178.

Strain gauge circuitry 172 such as analog-to-digital converter 174 and processing circuitry 176 may be mounted on board 60 (i.e., analog-to-digital converter 174 and processing circuitry 176 may be implemented in one or more components 62 on board 60) and/or circuitry such as analog-to-digital converter 174 and processing circuitry 176 may be mounted on flexible printed circuit 58 (e.g., using solder, wire bonds, etc.). Signal paths such as paths 180 and 182 may run between nodes N1 and N2 in bridge circuit 178 and analog-to-digital converter 174. To form low-resistance paths that are not subject to changes due to variations in strain, signal paths in strain gauge circuitry 172 such as paths 180 and 182 are preferably formed from low-resistivity materials such as copper and are implemented using larger layer thicknesses than the constantan layers used to implement the strain gauge resistors. Connections between the constantan (or other strain gauge resistor material used in forming the strain gauge resistors) and the copper (or other metal used in forming signal paths 180 and 182) of printed circuit 58 may be formed by overlapping, abutting, or otherwise coupling these metals at appropriate connection locations on printed circuit 58.

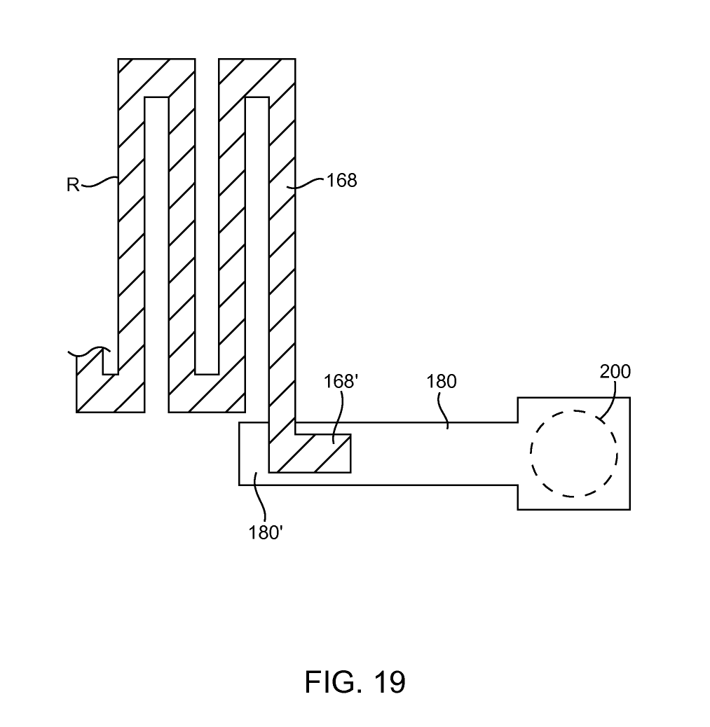

Consider, as an example, the arrangement of FIG. 19. As shown in FIG. 19, resistor R has been formed from a meandering resistor trace such as trace 168. Resistor trace 168 is preferably formed form a thin layer of a relatively high resistivity temperature insensitive material such as constantan. Signal path 180 has an end such as end 180′ that overlaps end 168′ of trace 168. Signal path 180 is electrically connected to trace 168 through the electrical connection formed from the direct contact between end 180′ and end 168′. End 168′ and end 180′ may be associated with node N1 in bridge circuit 178 of FIG. 17 (as an example). The resistor traces of node N2 may likewise be coupled to the end of path 182. Paths such as paths 180 and 182 may run along the length of flexible printed circuit 58 between the strain gauge resistors of strain gauge structure 150 and the electrical components of circuitry 172. Solder joints, wire bonds joints, or other electrical connections may be used to interconnect the metal of traces 180 and 182 to other interconnects and components, as shown by illustrative electrical connection 200 of FIG. 19. Electrical connection 200 may be, for example, a wire bond or a ball of solder that is formed directly on the exposed surface of trace 180.

Flexible printed circuit signal traces such as traces 180 and 182 may be formed form copper or other metals. Traces 180 and 182 may include elemental metals, metal alloys, multiple stacked layers, etc. For example, traces 180 and 182 may be formed form a layer of copper that is covered with a layer of nickel that is, in turn, coated with a layer of gold. Traces 180 and 182 may also be formed from metal alloys or other stacked layers of elemental metals and/or metal alloys. Connections between constantan or other metal in the strain gauge resistors and the metal of interconnects such as traces 180 and 182 in flexible printed circuit 58 may be formed using equipment and processing techniques of the type described in connection with FIG. 13.

An illustrative technique for forming connections between the strain gauge resistors of bridge circuit 178 and flexible printed circuit interconnects such as paths 180 and 182 of FIG. 17 is shown in FIGS. 20-29.

FIG. 20 is a cross-sectional side view of an illustrative flexible printed circuit substrate. Substrate 202 of FIG. 20 may be formed form a flexible sheet of polyimide or a flexible substrate layer of another polymer.

As shown in FIG. 21, flexible printed circuit substrate 202 may be coated with a thin metal layer such as layer 204 to form a seed layer for subsequent electrochemical deposition. Seed layer 204 may, for example, be a layer of copper or other metal that serves as a seed layer for subsequent copper electroplating operations. Layer 204 may, if desired, by patterned using photolithography.

Photolithographic patterning may also be used in forming the strain gauge resistors. As shown in FIG. 22, a photoresist layer such as photoresist layer 206 may be deposited and patterned on the surface of seed layer 204. The patterning process creates an opening such as opening 208 in the shape of strain gauge resistors for bridge network 178 (i.e., strain gauge structure 150).

After forming a photoresist layer with strain gauge resistor openings such as opening 208, strain gauge resistor metal may be deposited. For example, a metal alloy such as constantan or other metal may be deposited using sputter deposition or other physical vapor deposition techniques. The deposited strain gauge resistor metal fills opening 208 with strain gauge resistor metal 210.

After depositing metal 210, photoresist 206 may be stripped to remove undesired portions of the strain gauge metal layer and thereby form strain gauge resistors from metal 210 (i.e., a lift-off technique may be used to pattern strain gauge resistors from metal 210 as shown in FIG. 24). If desired, photolithographic patterning techniques based on metal etching may be used to pattern the strain gauge metal layer.

After patterning strain gauge metal layer 210 to form the strain gauge resistors, a photoresist layer may be formed on top of substrate 202, as shown in FIG. 25. Photoresist layer 212 may overlap patterned strain gauge metal 210 to protect strain gauge metal 210. Photolithographic patterning may be used to form openings in photoresist layer such as opening 214. The size and shapes of openings 214 may be selected to produce interconnect lines, solder pads, and other signal paths (see, e.g., paths 180 and 182 of FIG. 17). A portion of seed layer 204 is exposed within openings 214.

After openings 214 have been formed in photoresist layer 212, electroplating operations are used to electroplate metal 216 on the exposed portion of seed layer 204 in opening(s) 214. Metal 216 may be, for example, electroplated copper or a series of layers such as a copper layer covered by a nickel layer that is coated with a gold layer.

As shown in FIG. 27, photoresist layer 212 may then be removed from the flexible printed circuit, exposing patterned strain gauge metal 210 and plated copper 216. Because metal 210 and metal 216 overlap seed layer 204 and are formed directly on the surface of seed layer 204, metal layer 210 and metal 216 are shorted to seed layer 204. Metal layer 216 may be shorted to strain gauge metal 210 through the metal traces formed from the portion of seed layer 204 between metal 216 and metal 210 and/or metal 216 may abut or overlap metal 210 to short metal 216 to metal 210.

As shown in FIG. 28, a patterned polymer cover layer such as cover layer 218 (sometimes referred to as solder mask) may be formed on the surface of substrate 204 over metal 210 and metal 216 to form flexible printed circuit 58. Cover layer 218 may be formed using photoimageable polyimide or other photoimageable polymer, may be formed from a laminated polymer film (photoimageable or pre-patterned by cutting openings in the polymer), or may be formed using other cover layer arrangements. Cover layer 218 preferably has openings such as opening 220 that are aligned with metal 216.

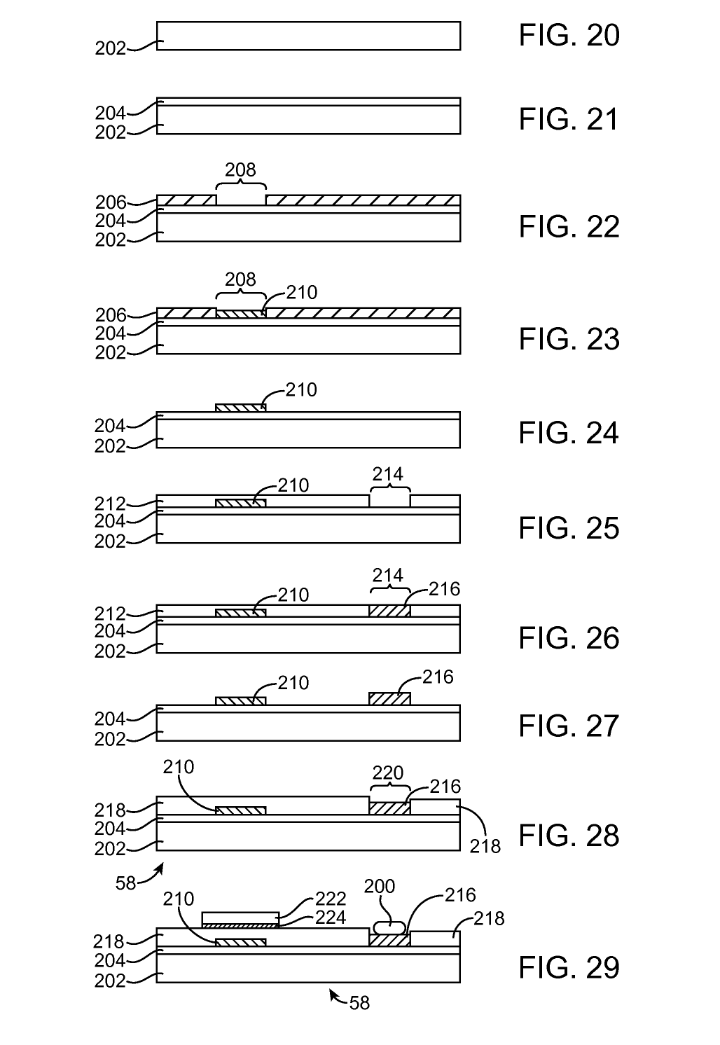

After forming flexible printed circuit 58 of FIG. 28, components may be attached to flexible printed circuit 58, as shown in FIG. 29. For example, a component such as component 222 may be attached to flexible printed circuit 58 using adhesive 224. Component 222 may be a fingerprint sensor such as fingerprint sensor 156 of FIG. 15 or other electrical component. Wire bonds, solder, or other conductive connections may be used in coupling fingerprint sensor 156 to the circuitry of flexible printed circuit 56, if desired. Component 222 may overlap strain gauge resistors 210. Conductive connections such as connection 200 (e.g., wire bonds, solder joints, etc.) may be formed to metal 216 through the openings (openings 220 of FIG. 28) in polymer layer 218, as illustrated in FIG. 29.

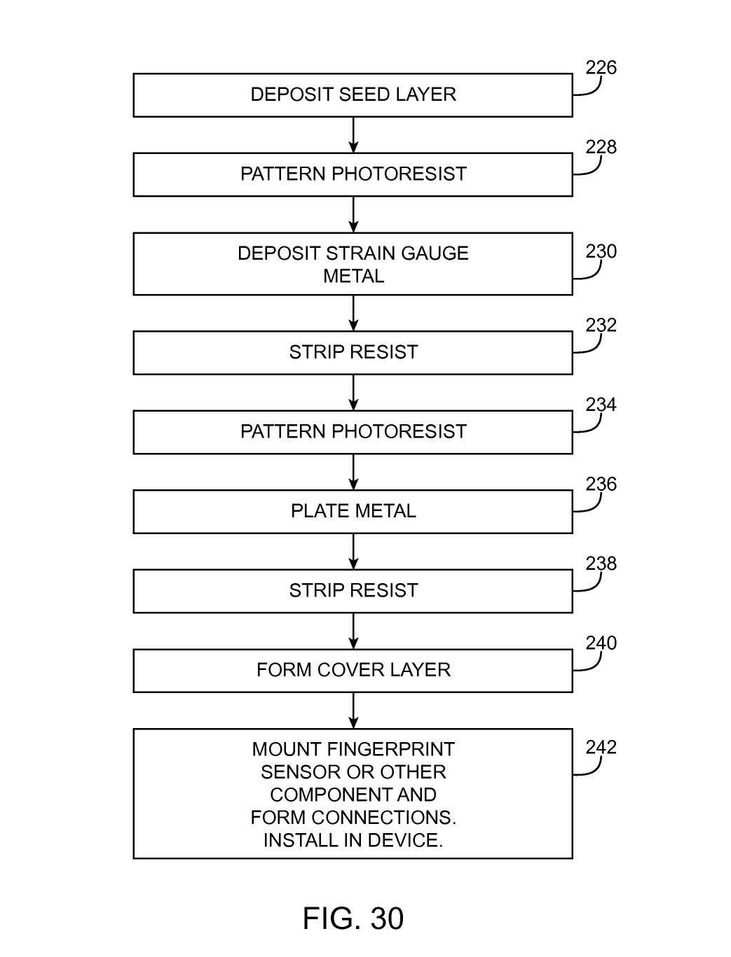

Illustrative steps involved in forming a flexible printed circuit such as flexible printed circuit 58 of FIG. 29 are shown in FIG. 30.

At step 226, seed layer 204 is deposited on flexible printed circuit substrate layer 202. Seed layer 204 may be a layer of metal such as a copper layer. Layer 204 may be patterned photolithographically, if desired.

At step 228, photoresist 206 may be deposited and patterned to form openings such as opening 208 of FIG. 24.

At step 230, a layer of strain gauge metal 210 such as a layer of constantan may be deposited.

At step 232, photoresist 206 may be removed, thereby patterning strain gauge metal layer 210 to form strain gauge resistors R1, R2, R3, and R4. Layer 210 may also be patterned using photolithographic etching, if desired.

At step 234, photoresist layer 212 may be deposited and photolithographically patterned to form openings 214.

Metal 216 may be formed in the exposed portion of seed layer 214 in openings 214 by electroplating (step 236).

Following removal of photoresist layer 212 (step 238), polymer cover layer 218 may be deposited and patterned to form openings such as opening 220 of FIG. 28 that are in alignment with metal 216 (step 240).

At step 242, a fingerprint sensor or other component may be mounted to flexible printed circuit 58 over strain gauge resistors 210 and wire bonds, solder connections, or other connections 200 may be formed to the metal contact pads formed from metal 216. Flexible printed circuit 58 may then be mounted in device 10.

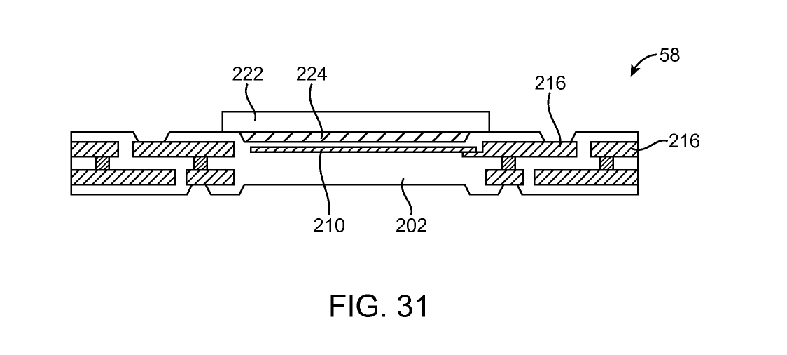

FIG. 31 is a cross-sectional side view of an illustrative flexible printed circuit of the type that may be formed using the operations of FIG. 30. As shown in FIG. 31, flexible printed circuit 58 may have a component such as a component 222 (e.g., a fingerprint sensor formed from a semiconductor die) that is attached to an upper surface of flexible printed circuit 58 by a layer of adhesive 224. Flexible printed circuit 58 may contain layers of metal and dielectric (see, e.g., dielectric 202). The dielectric of flexible printed circuit 58 may include one or more polyimide substrate layers and one or more polymer cover layers. Interconnects may be formed from metal traces in patterned metal layers of flexible printed circuit 58 such as traces 216 (e.g., vias and metal lines formed by electroplating and other deposition techniques). Strain gauge resistors 210 for a strain gauge may be located directly underneath fingerprint sensor 222 or may be formed elsewhere in flexible printed circuit 58.

If desired, a metal seed layer for flexible printed circuit 58 may be formed from a layer of metal foil that also serves as the strain gauge resistor layer. This type of arrangement is illustrated in connection with FIGS. 32-37.

Initially, a polymer substrate such as a layer of polyimide is provided (see, e.g., polyimide flexible printed circuit substrate 230 of FIG. 32).

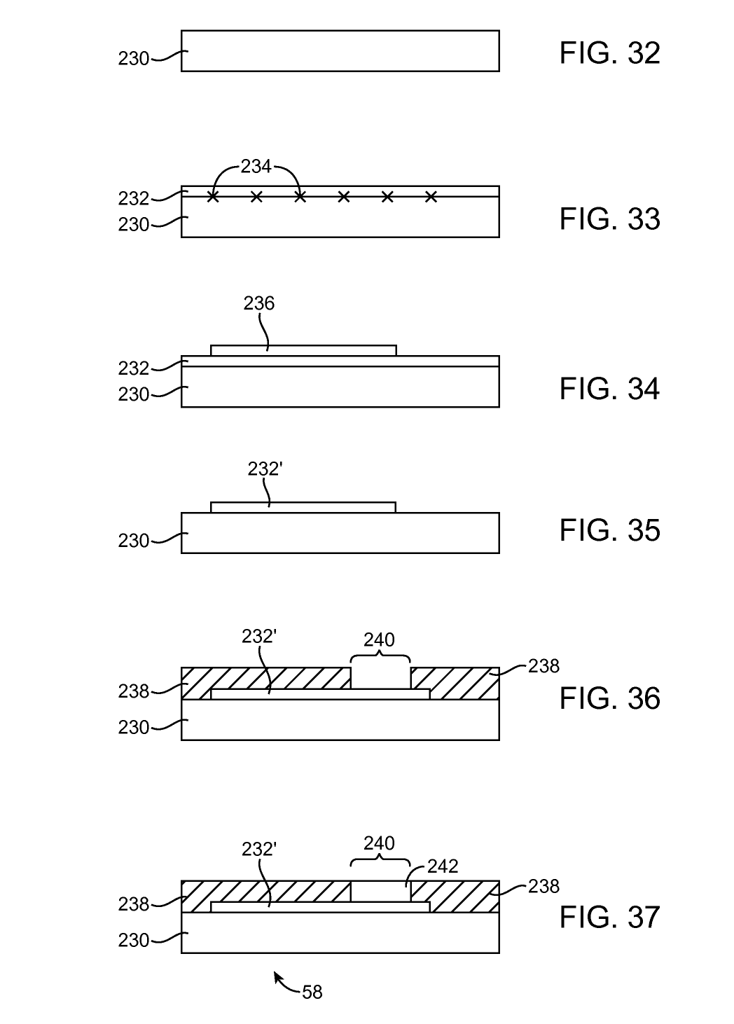

Using a layer of adhesive such as adhesive 234 of FIG. 33, metal layer foil 232 may be attached to the surface of flexible printed circuit substrate layer 230. Foil layer 232 may be, for example, patterned constantan foil (e.g., constantan foil that has been cut with a laser or die cutting tool or other equipment to form a desired pattern) or may be a uniform (unpatterned) layer of constantan foil or other metal that is to be patterned using photolithography and etching. For example, photoresist 236 may be deposited and patterned on the surface of foil 232 after attaching foil 232 to substrate 230, as shown in FIG. 34 and exposed portions of foil 232 may be etched away followed by photoresist stripping to leave patterned regions of foil layer 232′ as shown in FIG. 35. Regions 232′ may be used to form strain gauge resistors (e.g., resistors with meandering paths, co-located resistors, etc.) and may be used to form seed layer traces for supporting subsequent electroplating.

A layer of photoresist such as layer 238 of FIG. 36 may be deposited after forming patterned foil layer 232′ and may be patterned to form openings such as opening 240. Electroplating may then be used to form electroplated metal 242 on the exposed portion of foil layer 232′ in opening 240, as shown in FIG. 37. The exposed portion of layer 232′ is therefore able to serve as an electroplating seed layer for metal 242. If desired, photoresist 238 may be stripped and a polymer cover layer formed on the surface of flexible printed circuit 58 before components such as component 222 and connections such as connection 200 are added to flexible printed circuit 58.

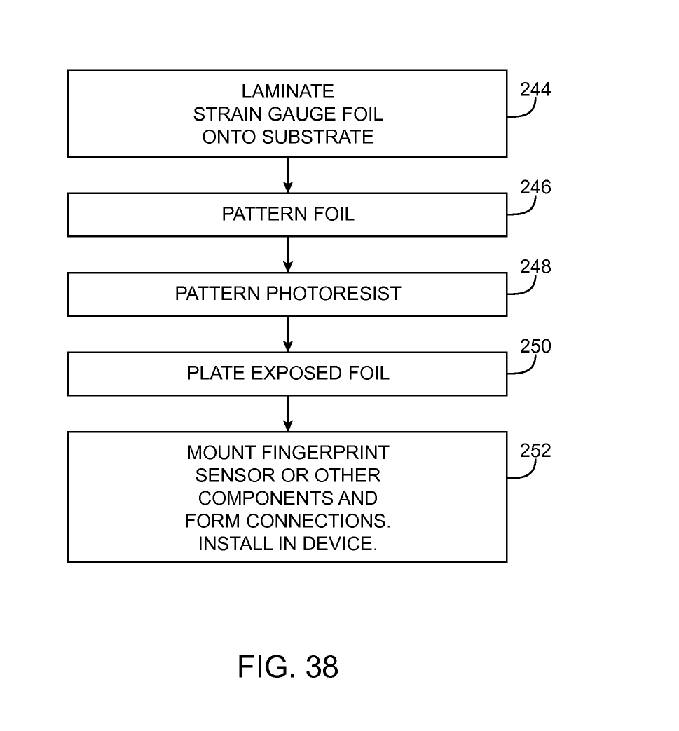

FIG. 38 is a flow chart of illustrative steps involved in forming flexible printed circuit 58 using operations of the type described in connection with FIGS. 32-37.

At step 244, foil layer 232 (e.g., a sheet of constantan or other strain gauge metal) may be laminated to polyimide substrate 230.

At step 246, patterning techniques such as photolithographic patterning techniques (e.g., photoresist patterning, etching, etc.) may be used to pattern the attached foil layer. The foil may be patterned to form strain gauge resistors and seed layer areas for subsequent electroplating.

At step 248, a layer of patterned photoresist may be formed on top of layer 232.

At step 250, electroplating operations may be used to grow copper or other metal on top of the exposed areas of the foil. The foil has a portion that forms the strain gauge resistors and a portion that serves as a seed layer for the electroplated metal.

At step 252, a patterned cover layer may be formed on the flexible printed circuit, a fingerprint sensor or other component may be mounted over the strain gauge, and electrical connections such as wire bonds and solder joints may be formed to the flexible printed circuit. The flexible printed circuit may then be installed in device 10.

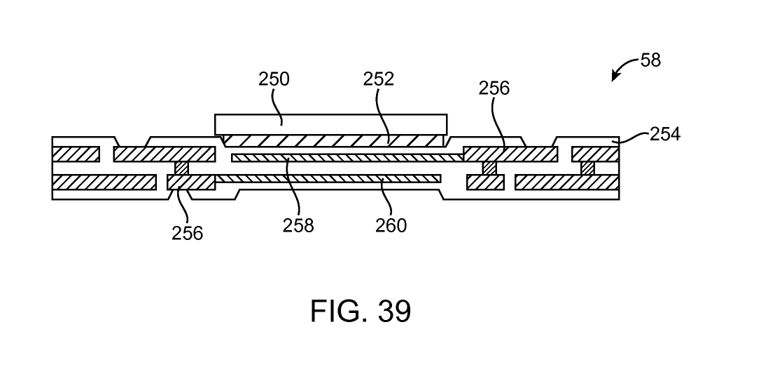

As shown in FIG. 39, flexible printed circuit 58 may, if desired, be provided with multiple overlapping strain gauge layers such as upper layer 258 and lower layer 260. Layer 258 may be patterned to form one or more strain gauge resistors in bridge circuit 178. Overlapping layer 260 may also be patterned to form one or more strain gauge resistors in bridge circuit 178. Metal traces 256 may be used in routing signals within flexible printed circuit 58 (e.g., to couple the strain gauge structures to strain gauge circuitry 172). Dielectric 254 (e.g., a polyimide flexible printed circuit substrate, upper and lower polymer cover layers, etc.) may be used in supporting and insulating the metal traces and other conductive structures of flexible printed circuit layer 58. For example, a polyimide substrate layer in dielectric 254 may have an upper surface on which layer 258 is formed and a lower surface on which layer 260 is formed. With this type of configuration, layers 258 and 260 may be used to form strain gauge resistors that overlap within the metal and dielectric flexible printed circuit layers of flexible printed circuit 58 and that overlap with component 250.

The foregoing is merely illustrative and various modifications can be made by those skilled in the art without departing from the scope and spirit of the described embodiments. The foregoing embodiments may be implemented individually or in any combination.

What is claimed is:

1. A flexible printed circuit, comprising:
flexible printed circuit layers including a metal trace; and
a strain gauge resistor formed from a meandering path of strain gauge metal in the flexible printed circuit layers, wherein the metal trace is coupled to the strain gauge metal.

2. The flexible printed circuit defined in claim 1 wherein the flexible printed circuit layers include a polymer substrate layer and wherein the strain gauge metal is formed on the polymer substrate layer.

3. The flexible printed circuit defined in claim 2 wherein the polymer substrate layer comprises a polyimide substrate layer.

4. The flexible printed circuit defined in claim 3 wherein the strain gauge metal comprises constantan.

5. The flexible printed circuit defined in claim 4 wherein the metal trace comprises copper.

6. The flexible printed circuit defined in claim 4 further comprising a polymer cover layer having an opening, wherein a portion of the metal trace is exposed in the opening.

7. The flexible printed circuit defined in claim 6 further comprising a wire bond on the portion of the metal trace that is exposed in the opening.

8. The flexible printed circuit defined in claim 6 further comprising solder on the portion of the metal trace that is exposed in the opening.

9. The flexible printed circuit defined in claim 6 further comprising an electrical component mounted on the flexible printed circuit layers that overlaps the strain gauge resistor.

10. The flexible printed circuit defined in claim 9 wherein the electrical component comprises a fingerprint sensor.

11. The flexible printed circuit defined in claim 10 wherein the strain gauge resistor comprises a portion of a strain gauge bridge circuit.

12. The flexible printed circuit defined in claim 11 wherein the strain gauge bridge circuit comprises an additional resistor and wherein the strain gauge resistor and the additional strain gauge resistor have parallel meandering paths.

13. The flexible printed circuit defined in claim 12 wherein the strain gauge resistor and the additional resistor comprise constantan foil attached to the polyimide substrate with a layer of adhesive.

14. The flexible printed circuit defined in claim 11 wherein the strain gauge bridge circuit comprises an additional strain gauge resistor and wherein the strain gauge resistor and the additional strain gauge resistor are formed in overlapping layers within the flexible printed circuit layers.

15. A flexible printed circuit, comprising:
a flexible polymer substrate layer;
a metal layer on the flexible polymer substrate layer;
a strain gauge resistor formed from strain gauge metal on a first portion of the metal layer; and
an electroplated metal trace on a second portion of the metal layer.

16. The flexible printed circuit defined in claim 15 wherein the strain gauge metal comprises constantan.

17. The flexible printed circuit defined in claim 16 wherein the second portion of the metal layer serves as an electroplating seed layer and wherein the electroplated metal trace comprises copper on the electroplating seed layer.

18. The flexible printed circuit defined in claim 17 further comprising an additional strain gauge resistor, wherein the strain gauge resistor has a first meandering trace and wherein the additional stain gauge resistor has a second meandering trace that runs alongside of the first meandering trace.

19. A flexible printed circuit, comprising:
a flexible polymer substrate layer;
a metal layer on the flexible polymer substrate layer, wherein a first portion of the metal layer is patterned to form a strain gauge resistor having a meandering trace and wherein a second portion of the metal layer serves as an electroplating seed layer; and
an electroplated metal layer on the second portion of the metal layer.

20. The flexible printed circuit defined in claim 19 wherein the metal layer comprises constantan.

21. The flexible printed circuit defined in claim 20 further comprising a fingerprint sensor overlapping the strain gauge resistor.
